(19) United States
(12) Patent Application Publication
(10) Pub. No.: US 2019/0181843 A1
(43) Pub. Date: Jun. 13, 2019

(54) DIVIDER - LOW POWER LATCH

(71) Applicant: QUALCOMM Incorporated, San Diego, CA (US)

(72) Inventors: Animesh PAUL, Bangalore (IN); Xinhua CHEN, San Diego, CA (US); Shailesh RAI, San Diego, CA (US)

(21) Appl. No.: 15/841,269

(22) Filed: Dec. 13, 2017

(51) Int. Cl. H03K 3/012; H03K 3/03; H03K 3/356

(52) U.S. Cl. CPC H03K 3/012; H03K 3/356104; H03K 3/0315

(57) ABSTRACT

Dividers based on quadrature ring oscillators using conventional latch devices can suffer from high current consumption. This is because there can be a number of short-circuit current paths during the output transitions of the conventional latch devices. To address this issue, a latch device with a novel locking cell is proposed. Unlike the conventional latch device, the transistors of the proposed locking cell may all be of a same transistor type. The configuration of the proposed locking cell eliminates a number of the short-circuit currents compared to the conventional latch device. As a result, power consumption can be reduced.

### FIELD OF DISCLOSURE

One or more aspects of the present disclosure generally relate to dividers, and in particular, to low power latch dividers.

### BACKGROUND

Dividers are used in many applications in which it is desired to generate I (In-phase) and Q (Quadrature) signals. For example, in a radio frequency (RF) transceiver, a VCO (voltage controlled oscillators) can be used to generate oscillating signals that are provided to a divider. The divider (e.g., a DIV2 (divide-by-two), a DIV4 (divide-by-four), etc.) in turn generate the I and Q signals from the VCO signals.

However, in many of the existing dividers, the design of the circuit is such that a significant amount of short-circuit current flows, and hence power consumption increases. This can present a significant issue in applications such as in mobile devices, especially when the mobile devices operate in high frequencies.

### SUMMARY

This summary identifies features of some example aspects, and is not an exclusive or exhaustive description of the disclosed subject matter. Whether features or aspects are included in, or omitted from this summary is not intended as indicative of relative importance of such features. Additional features and aspects are described, and will become apparent to persons skilled in the art upon reading the following detailed description and viewing the drawings that form a part thereof.

An exemplary latch device is disclosed. The latch device may comprise first and second input nodes, first and second output nodes, and first and second clock nodes. The latch device may also comprise first and second track inverters and a differential latch. The first track inverter may be configured to receive a first input signal from the first input node. The first track inverter may also be configured to output a first output signal to the first output node during a tracking mode. The first output signal may be logically complementary to the first input signal. The second track inverter may be configured to receive a second input signal from the second input node. The second input signal may be logically complementary to the first input signal. The second track inverter may also be configured to output a second output signal to the second output node during the tracking mode. The second output signal may be logically complementary to the second input signal. The differential latch may be configured to maintain the first output signal at the first output node and maintain the second output signal at the second output node during a locking mode. The tracking mode and the locking mode may be defined based on states of the first and second clock signals respectively received at the first and second clock nodes such that the first and second track inverters are enabled during the tracking mode and are disabled during the locking mode. The differential latch may comprise a plurality of latch transistors that are all of a same transistor type.

An exemplary ring oscillator is disclosed. The ring oscillator may comprise a plurality of latch devices connected in a ring configuration. Each latch device may comprise first and second input nodes, first and second output nodes, and first and second clock nodes. At least one latch device of the plurality of latch devices may also comprise first and second track inverters and a differential latch. The first track inverter may be configured to receive a first input signal from the first input node. The first track inverter may also be configured to output a first output signal to the first output node during a tracking mode. The first output signal may be logically complementary to the first input signal. The second track inverter may be configured to receive a second input signal from the second input node. The second input signal may be logically complementary to the first input signal. The second track inverter may also be configured to output a second output signal to the second output node during the tracking mode. The second output signal may be logically complementary to the second input signal. The differential latch may be configured to maintain the first output signal at the first output node and maintain the second output signal at the second output node during a locking mode. The tracking mode and the locking mode may be defined based on states of the first and second clock signals respectively received at the first and second clock nodes such that the first and second track inverters are enabled during the tracking mode and are disabled during the locking mode. The differential latch may comprise a plurality of latch transistors that are all of a same transistor type.

An exemplary method of operating a latch device is disclosed. The latch device may comprise first and second input nodes, first and second output nodes, and first and second clock nodes. The latch device may also comprise first and second track inverters and a differential latch. The method may comprise receiving, at the first track inverter, a first input signal from the first input node, and outputting, by the first track inverter, a first output signal to the first output node during a tracking mode. The first output signal may be logically complementary to the first input signal. The method may also comprise receiving, at the second track inverter, a second input signal from the second input node, and outputting, by the second track inverter, a second output signal to the second output node during the tracking mode. The second input signal may be logically complementary to the first input signal, and the second output signal may be logically complementary to the second input signal. The method may further comprise maintaining, by the differential latch, the first output signal at the first output node and the second output signal at the second output node during a locking mode. The tracking mode and the locking mode may be defined based on states of the first and second clock signals respectively received at the first and second clock nodes such that the first and second track inverters are enabled during the tracking mode and are disabled during the locking mode. The differential latch may comprise a plurality of latch transistors that are all of a same transistor type.

Another exemplary latch device is disclosed. The latch device may comprise first and second input nodes, first and second output nodes, and first and second clock nodes. The latch device may also comprise means for tracking and means for locking. The means for tracking may comprise means for tracking a first input signal and means for tracking a second input signal. The first and second input signals may be logically complementary to each other. The means for tracking the first input signal may be connected to the first input node, the first output node, and the first and second clock nodes. The means for tracking the first input signal may receive the first input signal from the first input node, and output a first output signal to the first output node during a tracking mode. The first output signal may be logically complementary to the first input signal. The means for tracking the second input signal may be connected to the second input node, the second output node, and the first and second clock nodes. The means for tracking the second input signal may receive the second input signal from the second input node, and output a second output signal to the second output node during the tracking mode. The second output signal may be logically complementary to the second input signal. The means for locking may maintain the first output signal at the first output node and maintain the second output signal at the second output node during a locking mode. The tracking mode and the locking mode may be defined based on states of the first and second clock signals respectively received at the first and second clock nodes such that the means for tracking is enabled during the tracking mode and is disabled during the locking mode. The means for locking may comprise a plurality of locking transistors that are all of a same transistor type.

### BRIEF DESCRIPTION OF THE DRAWINGS

The accompanying drawings are presented to aid in the description of examples of one or more aspects of the disclosed subject matter and are provided solely for illustration of the examples and not limitation thereof:

FIG. 1 illustrates a logical diagram of a conventional ring oscillator;

FIG. 2 illustrates a detailed logic diagram of a latch device of the conventional ring oscillator of FIG. 1;

FIG. 3 illustrates a diagram of a conventional quadrature ring oscillator;

FIG. 4 illustrates a circuit diagram of a latch device of the conventional quadrature ring oscillator of FIG. 3;

FIG. 5 illustrates short-circuit currents that flow in the conventional latch device;

FIG. 6 illustrates a diagram of an example divider according to an aspect of the present disclosure;

FIG. 7 illustrates a circuit diagram of an example latch device of the divider of FIG. 6 according to an aspect of the present disclosure;

FIG. 8 illustrates short-circuit current that flows in the example latch device of FIG. 6 according to an aspect of the present disclosure;

FIG. 9 illustrates a configuration of an example differential latch of the latch device of FIG. 7 according to an aspect of the present disclosure;

FIG. 10 illustrates a circuit diagram of another example latch device of the divider of FIG. 6 according to an aspect of the present disclosure;

FIG. 11 illustrates a configuration of an example differential latch of the latch device of FIG. 10 according to an aspect of the present disclosure;

FIG. 12 illustrates a flow chart of an example method performed by the latch device of FIGS. 7 and/or 10;

FIG. 13 illustrates examples of devices with a divider and/or latch device integrated therein.

### DETAILED DESCRIPTION

Aspects of the subject matter are provided in the following description and related drawings directed to specific examples of the disclosed subject matter. Alternates may be devised without departing from the scope of the disclosed subject matter. Additionally, well-known elements will not be described in detail or will be omitted so as not to obscure the relevant details.

The word “exemplary” is used herein to mean “serving as an example, instance, or illustration.” Any embodiment described herein as “exemplary” is not necessarily to be construed as preferred or advantageous over other embodiments. Likewise, the term “embodiments” does not require that all embodiments of the disclosed subject matter include the discussed feature, advantage or mode of operation.

The terminology used herein is for the purpose of describing particular examples only and is not intended to be limiting. As used herein, the singular forms “a”, “an” and “the” are intended to include the plural forms as well, unless the context clearly indicates otherwise. It will be further understood that the terms “comprises”, “comprising”, “includes” and/or “including”, when used herein, specify the presence of stated features, integers, processes, operations, elements, and/or components, but do not preclude the presence or addition of one or more other features, integers, processes, operations, elements, components, and/or groups thereof.

Further, many examples are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, these sequence of actions described herein can be considered to be embodied entirely within any form of computer-readable storage medium having stored therein a corresponding set of computer instructions that upon execution would cause an associated processor to perform the functionality described herein. Thus, the various aspects may be embodied in a number of different forms, all of which have been contemplated to be within the scope of the claimed subject matter. In addition, for each of the examples described herein, the corresponding form of any such examples may be described herein as, for example, “logic configured to” perform the described action.

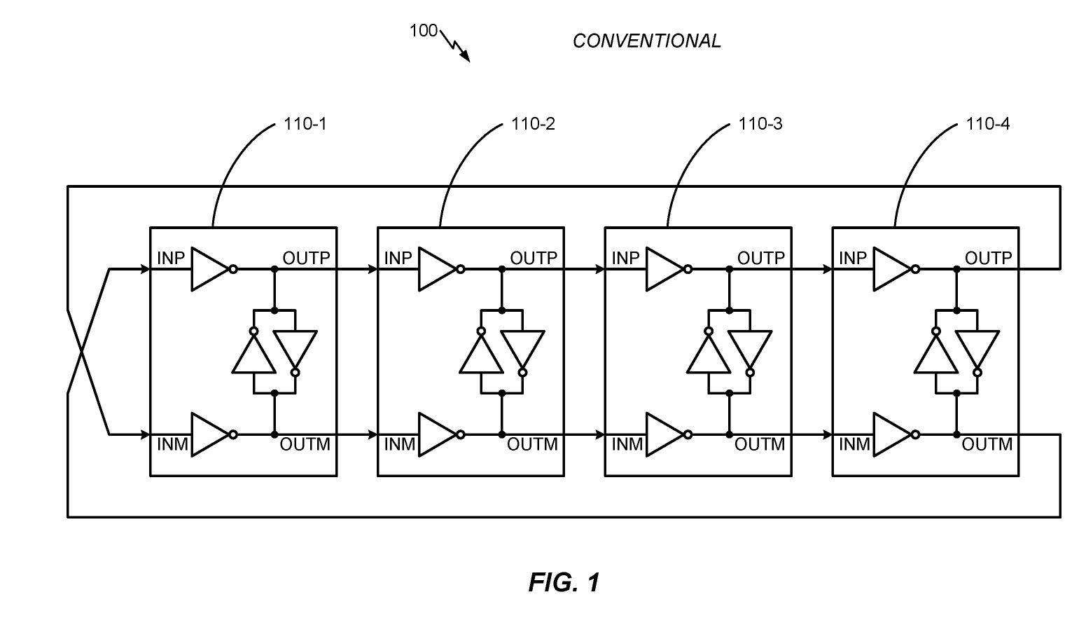

FIG. 1 illustrates a logical diagram of a conventional divider 100. In this instance, the divider 100 is a ring oscillator. The divider 100 includes four latch devices 110-1, 110-2, 110-3 and 110-4 connected to each other. The latch devices 110-1 . . . 110-4 are all identical to each other.

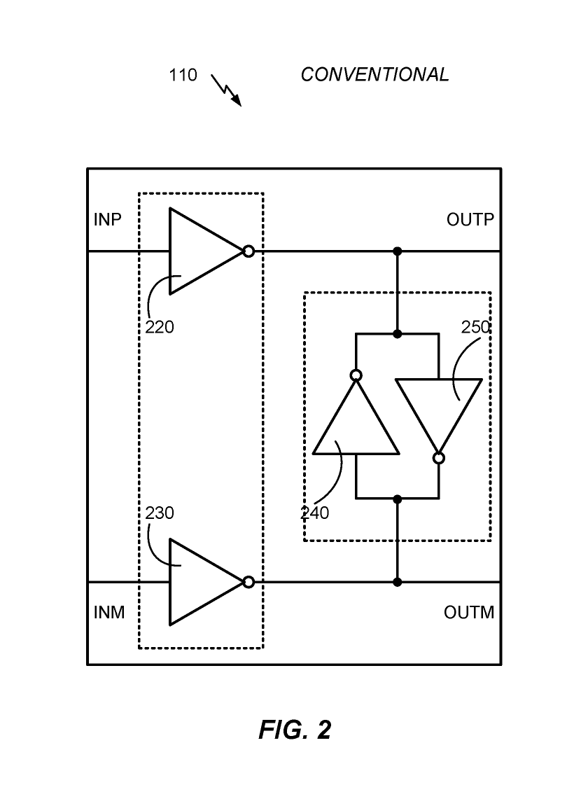

FIG. 2 illustrates a detailed logic diagram of a latch device 110 of the conventional divider 100. The latch device 100 includes a tracking cell and a locking cell. The tracking cell includes first and second track inverters 220, 230 (enclosed by a dashed rectangle), and the locking cell includes first and second lock inverters 240, 250 (enclosed by another dashed rectangle).

The tracking cell receives the differential input signals INP, INM and outputs the differential output signals OUTP, OUTM. More specifically, the first track inverter 220 receives the first input signal INP and outputs the first output signal OUTP. The signals INP and OUTP are complementary. Conversely, the second track inverter 230 receives the second input signal INM and outputs the second output signal OUTM. The signals INM and OUTM are also complementary. Since the first and second input signals INP, INM are complementary, the first and second output signals OUTP, OUTM are also complementary.

The locking cell maintains the output signals OUTP, OUTM at the first and second output nodes at the values outputted by the tracking cell until the inputs to the tracking cell change. The first and second lock inverters 240, 250 are back-to-back connected to each other.

Referring back to FIG. 1, the latch devices 110-1 . . . 110-4 are connected in a ring configuration. More specifically, between immediately adjacent latch devices (e.g., between first and second latch devices 110-1, 110-2), the first and second output nodes of the previous latch device (e.g., the first latch device 110-1) are respectively connected to the first and second input nodes of the subsequent latch device (e.g., the second latch device 110-2).

However, the connections between last and first latch devices 110-4, 110-1 are reversed. Specifically, the first and second output nodes of the fourth latch device 110-4 are respectively connected to the second and first input nodes of the first latch device 110-1. As a result, a ring of eight inverters is formed.

If the locking cells of the latch devices 110 are disregarded for the moment, then since the number of inverters in the ring is even, the ring will reach a stable state, i.e., will not oscillate. It is the presence of the locking cells, which force differential signals to be provided at the output nodes of each latch device 110 that enable the conventional divider 100 to oscillate.

The oscillation frequency of the divider 100 depends on the delays of the circuit used to implement the divider 100. This means that frequencies can vary widely depending on the design of the latch devices 110. Even within a particular circuit design, frequencies can still vary due to manufacturing variations.

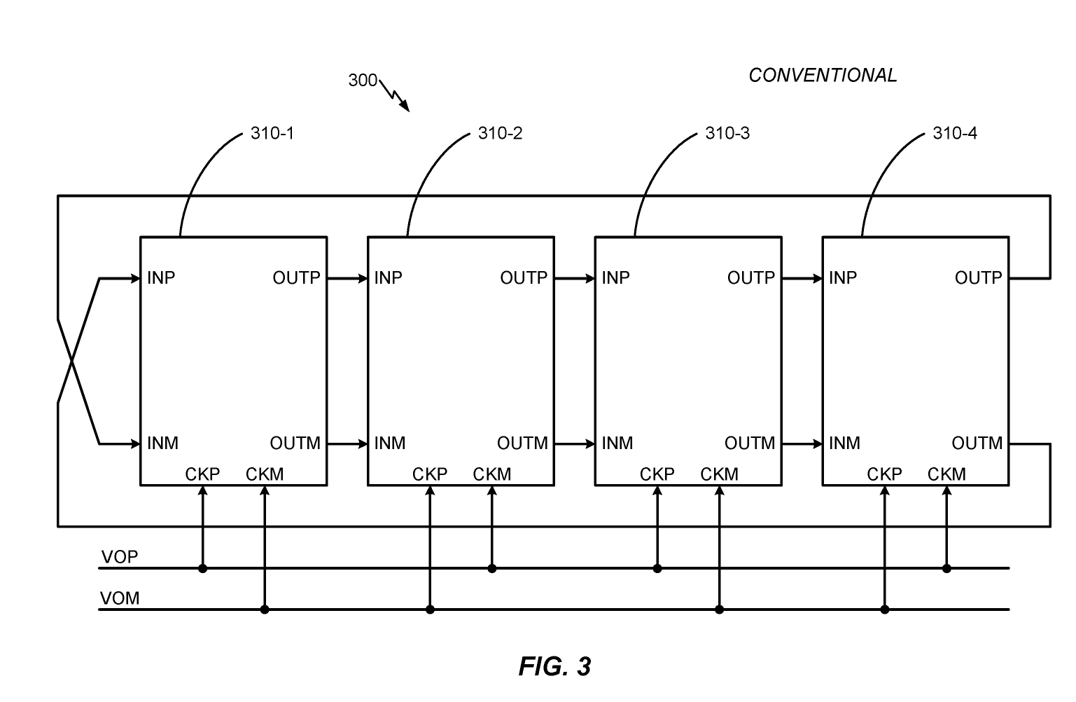

It is thus desirable to control the frequency of the divider outputs. FIG. 3 illustrates a diagram of a conventional diver 300 whose output frequency can be externally controlled. In this instance, the divider 300 is a DIV4 (divide-by-four) quadrature ring oscillator. Similar to the divider 100 of FIG. 1, the divider 300 also includes four latch devices 310-1, 310-2, 310-3 and 310-4 connected to each other in a ring configuration.

But in addition, each of the latch devices 310-1, 310-2, 310-3 and 310-4 also include first and second clock nodes that receive first and second clock signals CKP, CKM which are externally provided. For example, a VCO (voltage controlled oscillator) outputting differential signals VOP, VOM may be provided as the clock signals. Note that the VOP and VOM signals are alternately provided to the clock nodes of adjacent latch devices 310. For example, the VOP (VOM) signal is provided to the first (second) clock node of the first and third latch devices 310-1, 310-3 and to the second (first) clock node of the second and fourth latch devices 310-2, 310-4. As a result, the frequency of the outputs OUTP, OUTM of each latch device 310 is a fourth of the frequency of the VOP, VOM signals (hence DIV4). Also, the phases of the outputs of the each latch device 310 are different from the phases of the outputs of other latch devices 310. While not shown, the outputs of two latch devices 310 may be provided as the I and Q signals.

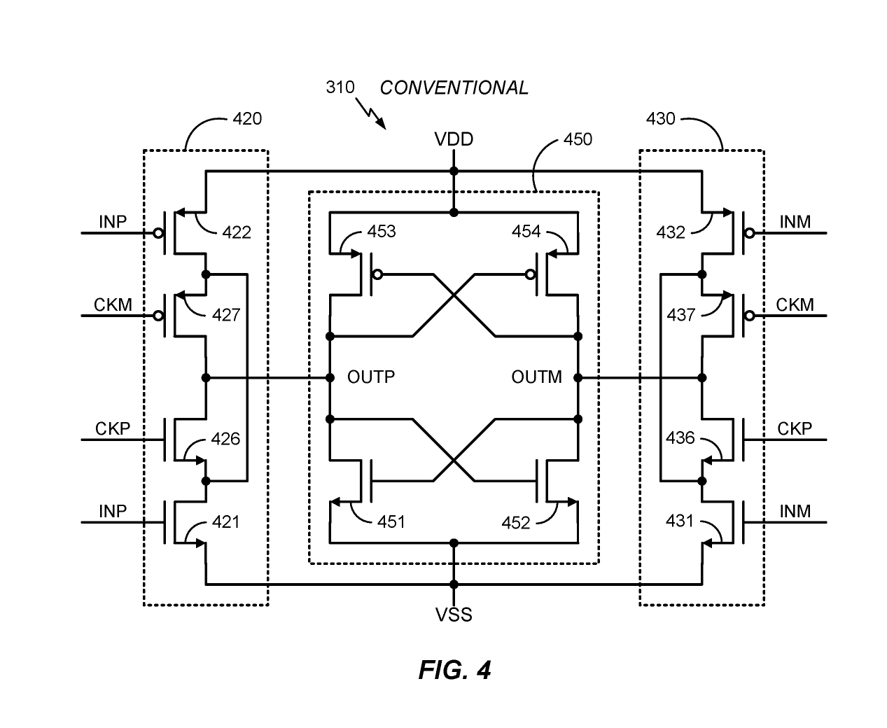

In FIG. 3, the latch devices 310-1 . . . 310-4 are all identical to each other. FIG. 4 illustrates an example circuit diagram of the latch device 310 of the divider 300. The latch device 310 includes a tracking cell and a locking cell. The tracking cell includes first and second track inverters 420, 430 and the locking cell includes a differential latch 450. The tracking cell receives the differential input signals INP, INM and outputs the differential output signals OUTP, OUTM. More specifically, the first track inverter 420 receives the first input signal INP from the first input node and outputs the first output signal OUTP to the first output node when the first track inverter 420 is enabled. Conversely, the second track inverter 430 receives the second input signal INM from the second input node and outputs the second output signal OUTM to the second output node when the second track inverter 430 is enabled. The first and second track inverters 420, 430 are enabled and disabled by the first and second clock signals CKP, CKM received at the first and second clock nodes.

The first track inverter 420 includes a first input transistor 421, a first clock transistor 426, a second clock transistor 427, and a second input transistor 422 connected in series between ground and V_{DD}. The first input transistor 421 is an NMOS transistor. The source of the first input transistor 421 is connected to ground, and the gate thereof is connected to the first input node to receive the first input signal INP. The first clock transistor 426 is also an NMOS transistor. The source of the first clock transistor 426 is connected the drain of the first input transistor 421, and the gate thereof is connected to the first clock node to receive the first clock signal CKP. The drain of the first clock transistor 426 is connected to the first output node. The second clock transistor 427 is a PMOS transistor. The drain of the second clock transistor 427 is connected to the drain of the first clock transistor 426 and also to the first output node. The gate of the second clock transistor 427 is connected to the second clock node to receive the second clock signal CKM. The second input transistor 422 is also a PMOS transistor. The source of the second input transistor 422 is connected to the supply voltage V_{DD}, and the gate thereof is connected to the first input node to receive the first input signal INP. The drain of the second input transistor 422 is connected to the source of the second clock transistor 427.

The second track inverter 430 includes a first complementary input transistor 431, a first complementary clock transistor 436, a second complementary clock transistor 437, and a second complementary input transistor 432 connected in series between ground and V_{DD}. The first complementary input transistor 431 is an NMOS transistor. The source of the first complementary input transistor 431 is connected to ground, and the gate thereof is connected to the second input node to receive the second input signal INM. The first complementary clock transistor 436 is also an NMOS transistor. The source of the first complementary clock transistor 436 is connected the drain of the first complementary input transistor 431, and the gate thereof is connected to the first clock node to receive the first clock signal CKP. The drain of the first complementary clock transistor 436 is connected to the second output node. The second complementary clock transistor 437 is a PMOS transistor. The drain of the second complementary clock transistor 437 is connected to the drain of the first complementary clock transistor 436 and to the second output node. The gate of the second complementary clock transistor 437 is connected to the second clock node to receive the second clock signal CKM. The second complementary input transistor 432 is also a PMOS transistor. The source of the second complementary input transistor 432 is connected to the supply voltage V_{DD}, and the gate thereof is connected to the second input node to receive the second input signal INM. The drain of the second complementary input transistor 432 is connected to the source of the second complementary clock transistor 437.

The differential latch 450 includes first and second pulldown transistors 451, 452 and first and second pullup transistors 453, 454. The first and second pulldown transistors 451, 452 are NMOS transistors that are cross-connected to each other. In particular, the sources of the first and second pulldown transistors 451, 452 are connected to ground. The drains of the first and second pulldown transistors 451, 452 are respectively connected to the first and second output node. The drain of the first pulldown transistor 451 is connected to the gate of the second pulldown transistor 452, and vice versa.

The first and second pullup transistors 453, 454 are PMOS transistors that are cross-connected to each other. In particular, the sources of the first and second pullup transistors 453, 454 are connected to the supply voltage V_{DD}. The drains of the first and second pullup transistors 453, 454 are respectively connected to the first and second output node, and hence respectively to the drains of the first and second pulldown transistors 451, 452. The drain of the first pullup transistor 451 is connected to the gate of the second pullup transistor 452, and vice versa.

With the conventional latch device 310, when the first clock signal CKP is high and the second clock signal CKM is low, the first and second clock transistors 426, 427 are turned on, thereby enabling the first track inverter 420 to track the first input signal INP. The first and second complementary clock transistors 436, 437 are also turned on, thereby enabling the second track inverter 430 to track the second input signal INM. When enabled, the first track inverters 420 inverts the first input signal INP and provides the inverted signal as the first output signal OUTP to the first output node. Similarly, the second track inverters 430 inverts the second input signal INM and provides the inverted signal as the second output signal OUTM to the second output node.

The differential latch 450 locks the first and second output signals OUTP, OUTM at the first and second output nodes when the first and second track inverters 420, 430 are disabled. In other words, the differential latch 450 maintains the first and second output signals OUTP, OUTM when the first and second clock signals CKP, CKM are respectively low and high. For example, if the first (second) output signal OUTP (OUTM) is logically high (low), the second pulldown transistor 452 (the first pullup transistor 453) is turned on and the second pullup transistor 454 (the first pulldown transistor 451) is turned off. As a result, the first (second) output signal CKP (CKM) is maintained at the logical high (low) voltage.

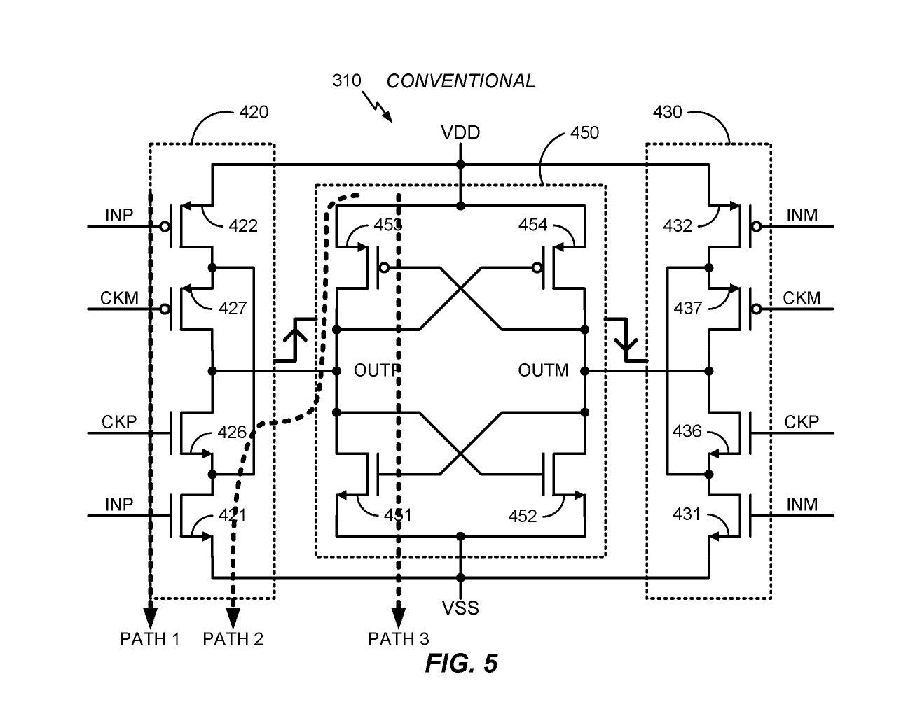

Recall from above that in conventional dividers, the design of the circuit is such that a significant amount of short-circuit current flows, which leads to increased power consumption. This is shown in FIG. 5 which illustrates the various short-circuit currents that flow in the conventional latch device 310 when the output signals OUTP, OUTM transition.

In FIG. 5, it is assumed that the first (second) output signal OUTP (OUTM) is transitioning from low to high (high to low). During the first output signal OUTP transition, there can be at least the following shirt-circuit current paths. In path 1, current can flow from V_{DD} to ground through the first track inverter 420. For example, for at least some portion of the duration of the transition, the first and second input transistors 421, 422 may both be turned on. In path 2, short-circuit current between V_{DD} to ground can flow through the first pullup transistor 453, the first clock transistor 426, and the first input transistor 421. In path 3, short-circuit current between V_{DD} to ground can flow through the differential latch 450 itself. While not shown, short-circuit currents may also flow through the second track inverter 430 (similar to path 1), flow through parts of the differential latch 450 and the second track inverter (similar to path 2).

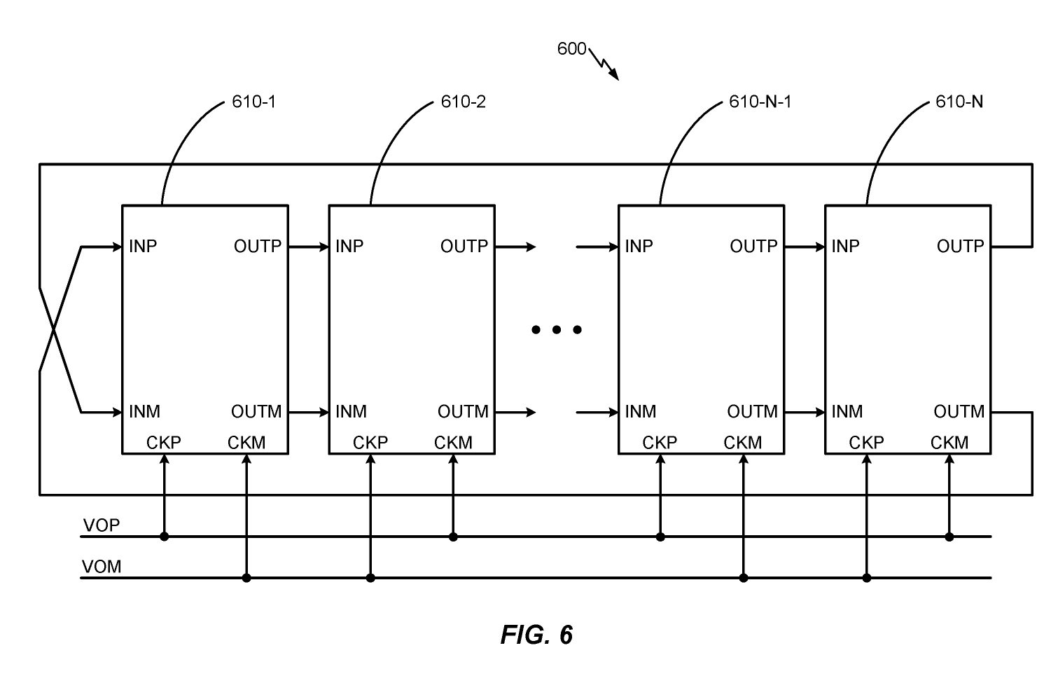

FIG. 6 illustrates a diagram of an example divider 600 that addresses one or more issues of conventional dividers. The divider 600 may be a DIVN (divide-by-N) quadrature ring oscillator. N may be any even number 2 or greater. The divider 600 may comprise latch devices 610-n, n=1, 2, . . . , N. Each latch device 610-n may include first and second clock nodes configured to receive first and second clock signals CKP, CKM. In an aspect, the first and second clock signals CKP, CKM may be externally provided, e.g., from a VCO outputting external differential clock signals VOP, VOM.

The external clock signals VOP, VOM signals may be alternately provided to the first and second clock nodes of adjacent latch devices 610. For example, the VOP (VOM) signal may be provided to the first (second) clock node of every odd latch device 610, and the VOM (VOP) signal may be provided to the first (second) clock node of every even latch device 610.

The latch devices 610 may be connected in a ring configuration. That is, between immediately adjacent latch devices 610-n, 610-(n+1), the first and second output nodes of the previous latch device 610-n may respectively be connected to the first and second input nodes of the subsequent latch device 610-(n+1). For example, the first and second output nodes of the first latch device 610-1 may respectively be connected to the first and second input nodes of the second latch device 610-2. However, the connections between last and first latch devices 610-N, 610-1 may be reversed. Specifically, the first and second output nodes of the last latch device 610-N may respectively be connected to the second and first input nodes of the first latch device 610-1.

It should be noted that the term “connected” will be used extensively in describing the various aspects of the disclosure. It is intended that the term be interpreted broadly to include electrical coupling in which there may or may not be intervening elements between the coupling elements.

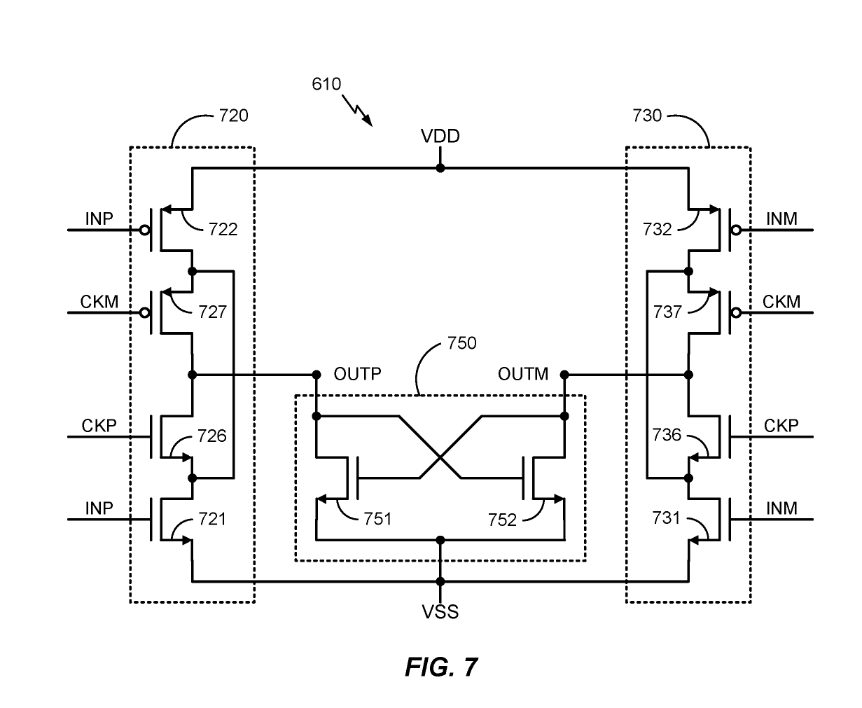

FIG. 7 illustrates a circuit diagram of an example latch device 610. The latch device 610 of FIG. 7 may represent one, some or all of the latch devices 610-n of the divider 600. The latch device 610 may include a tracking cell and a locking cell. The tracking cell may include first and second track inverters 720, 730 and the locking cell may include a differential latch 750. The tracking cell may include first and second track inverters 720, 730 that are configured to receive the differential input signals INP, INM and output the differential output signals OUTP, OUTM. More specifically, the first track inverter 720 may be connected to the first input node, the first output node, and the first and second clock nodes. The first track inverter 720 may be configured to receive the first input signal INP from the first input node and output the first output signal OUTP to the first output node when the first track inverter 720 is enabled. The second track inverter 730 may be connected to the second input node, the second output node, and the first and second clock nodes. The second track inverter 730 may be configured to receive the second input signal INM from the second input node and output the second output signal OUTM to the second output node when the second track inverter 730 is enabled.

The first and second track inverters 720, 730 may be enabled and disabled by the first and second clock signals CKP, CKM received at the first and second clock nodes. For ease of description, the latch device 610 may be viewed as being in a tracking mode when the first and second track inverters 720, 730 are enabled. Conversely, the latch device 610 may be viewed as being in a locking mode when the first and second track inverters 720, 730 are disabled. Thus, in an aspect, the tracking and the locking modes may be defined by the states of the first and second clock signals CKP, CKM respectively received at the first and second clock nodes such that the first and second track inverters 720, 730 are enabled during the tracking mode and are disabled during the locking mode.

Referring back to FIG. 6, recall that the differential signals VOP, VOM are alternately provided to the first and second clock nodes of adjacent latch devices 610-n, 610-(n+1). This means that when the latch device 610-n is in the tracking mode, the adjacent latch device 610-(n+1) is in the locking mode.

Referring to FIG. 7 again, the first track inverter 720 may be configured similarly to the first track inverter 420 (see FIG. 4). That is, the first track inverter 720 may include a first input transistor 721, a first clock transistor 726, a second clock transistor 727, and a second input transistor 722 all connected in series between low and high supply voltages (labeled as V_{SS} and V_{DD}, respectively). The first input transistor 721 may be an NMOS transistor, in which the source thereof may be connected to the low supply voltage, and the gate thereof may be connected to the first input node to receive the first input signal INP. The first clock transistor 726 may also be an NMOS transistor, in which the source thereof may be connected the drain of the first input transistor 721, the gate thereof may be connected to the first clock node to receive the first clock signal CKP, and the drain thereof may be connected to the first output node. The second clock transistor 727 may be PMOS transistor in which the drain thereof may be connected to the drain of the first clock transistor 726, and may also be connected to the first output node. The gate of the second clock transistor 727 may be connected to the second clock node to receive the second clock signal CKM. The second input transistor 722 may also be a PMOS transistor, in which the source thereof may be connected to the high supply voltage, and the gate thereof may be connected to the first input node to receive the first input signal INP. The drain of the second input transistor 722 may be connected to the source of the second clock transistor 727.

The second track inverter 730 may also be configured similarly to the second track inverter 720 (see FIG. 4). That is, the second track inverter 730 may include a first complementary input transistor 731, a first complementary clock transistor 736, a second complementary clock transistor 737, and a second complementary input transistor 732 all connected in series between the low and high supply voltages. The first complementary input transistor 731 may be an NMOS transistor, in which the source thereof may be connected to the low supply voltage, and the gate thereof may be connected to the second input node to receive the second input signal INM. The first complementary clock transistor 736 may also be an NMOS transistor, in which the source thereof may be connected the drain of the first complementary input transistor 731, the gate thereof may be connected to the first clock node to receive the first clock signal CKP, and the drain thereof may be connected to the second output node. The second complementary clock transistor 737 may be a PMOS transistor, in which the drain thereof may be connected to the drain of the first complementary clock transistor 736, and may also be connected to the second output node. The gate of the second complementary clock transistor 737 may be connected to the second clock node to receive the second clock signal CKM. The second complementary input transistor 732 may also be a PMOS transistor, in which the source thereof may be connected to the high supply voltage, and the gate thereof may be connected to the second input node to receive the second input signal INM. The drain of the second complementary input transistor 732 may be connected to the source of the second complementary clock transistor 737.

It should be noted that the first and second track inverters are not limited to the example first and second track inverters 720, 730. Any configuration of inverters that are configured to invert the input signals during the tracking mode may be contemplated.

The differential latch 750 can be significantly different from the conventional differential latch 450 (compare FIGS. 4 and 7). The differential latch 750 may include first and second pulldown transistors 751, 752 cross-connected to each other. The first and second pulldown transistors 751, 752 may be NMOS transistors whose sources may be connected to the low supply voltage. The drains of the first and second pulldown transistors 751, 752 may respectively be connected to the first and second output nodes. The drain of the first pulldown transistor 751 and the first output node may be connected to the gate of the second pulldown transistor 752. Conversely, the drain of the second pulldown transistor 752 and the second output node may be connected to the gate of the first pulldown transistor 751.

Note that the differential latch 750 only includes NMOS transistors. More generally, it can be said that the differential latch 750 may include a plurality of latch transistors that are all of a same transistor type. Also note that the differential latch 750 is not directly connected to the high supply voltage. The differential latch 750 may be electrically coupled to the high supply voltage only through the first and/or the second track inverters 720, 730.

During the tracking mode when the first clock signal CKP is high and the second clock signal CKM is low, the first and second clock transistors 726, 727 may be turned on, thereby enabling the first track inverter 720 to track the first input signal INP. The first and second complementary clock transistors 736, 737 may also be turned on during the tracking mode, thereby enabling the second track inverter 730 to track the second input signal INM. During the tracking mode, the first track inverters 720 may invert the first input signal INP and provide the inverted signal as the first output signal OUTP to the first output node. The second track inverters 730 may invert the second input signal INM and provide the inverted signal as the second output signal OUTM to the second output node.

The differential latch 750 may be configured to lock the first and second output signals OUTP, OUTM at the first and second output nodes when the first and second track inverters 720, 730 are disabled, i.e., during the locking mode. That is, the differential latch 750 may be configured to maintain the first and second output signals OUTP, OUTM during the locking mode when the first and second clock signals CKP, CKM are respectively low and high. Importantly, the differential latch 750 may maintain the differential gain requirement of the first and second output signals OUTP, OUTM. That is, when the first output signal OUTP goes high, the second output signal OUTM is pulled low by the first and second pulldown transistors 751, 752 and vice versa. In an aspect, the differential latch 750 may be referred to as a pulldown half latch whereas the differential latch 450 may be referred to as a full latch.

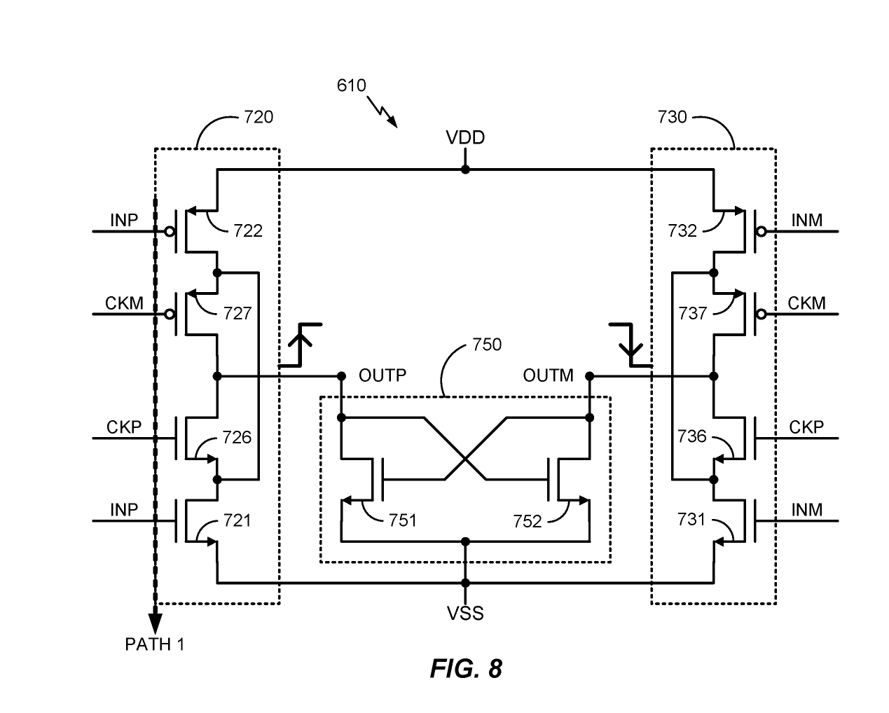

The amount of short-circuit current can be reduced significantly with the differential latch 750. This is shown in FIG. 8 which illustrates the short-circuit current that flows in the latch device 610 when the first and second output signals OUTP, OUTM are transitioning. In FIG. 8, it is again assumed that the first (second) output signal OUTP (OUTM) is transitioning from low to high (high to low) logic voltages. In this instance, there may still be the short-circuit current path 1 through the first track inverter 720.

However, in an aspect, the short-circuit current paths 2 and 3 can be eliminated. That is, the differential latch 750 may be configured such that no current flows directly through the differential latch 750 between the high and low supply voltages when the first and second output signals OUTP, OUTM transition between logical voltages. As a result, current consumption, and hence power consumption, can be reduced.

As indicated above, it may be desirable to maintain the differential gain requirement, i.e., the first and second output signals OUTP, OUTM should be maintained as complementary signals. In other words, the first and second pulldown transistors 751, 752 should have sufficient driving capabilities. One technique to enhance the driving capability of a transistor is to fabricate the transistor to be physically big. For example, one or both of the first and second pulldown transistors 751, 752 may be dimensioned to be fabricated over a large area of a semiconductor.

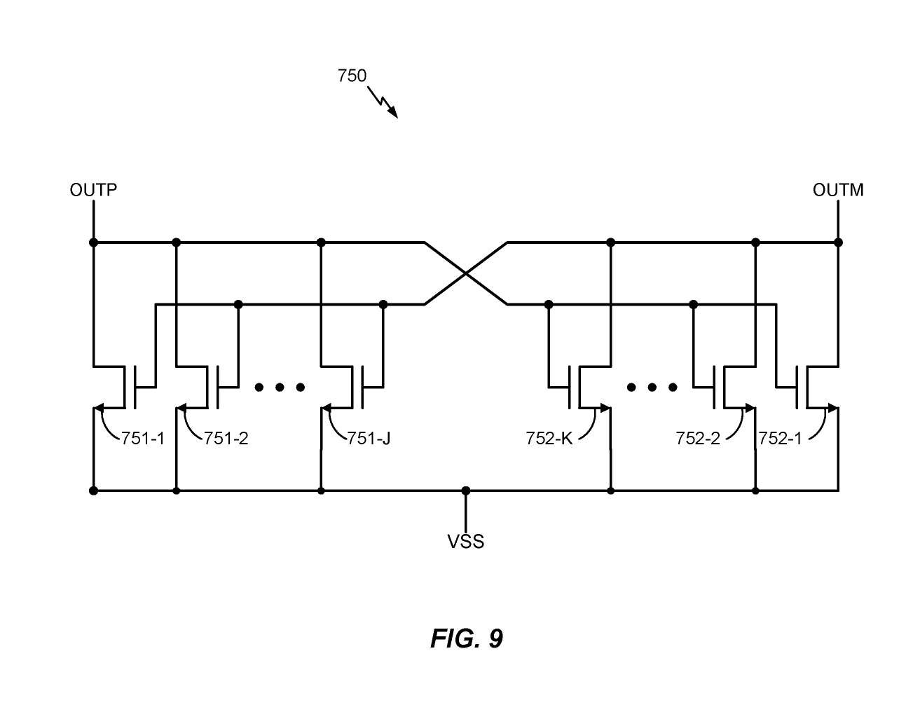

Another technique is to provide multiple transistors and connect them in parallel with each other. For example, as illustrated in FIG. 9, the first pulldown transistor 751 may be implemented to comprise a first plurality of pulldown transistors 751-j, where j=1 . . . J, and the second pulldown transistor 752 may be implemented to comprise a second plurality of pulldown transistors 752-k, where k=1 . . . K. The numbers J and K can be equal to each other or different from each other.

The first and second pluralities of pulldown transistors 751-j, 752-k may be NMOS transistors whose sources may be connected to the low supply voltage. The drains of the first and second pluralities of pulldown transistors 751-j, 752-k may respectively be connected to the first and second output nodes. The gates of the first pulldown transistors 751-j may be connected to the second output node, and the gates of the second pulldown transistors 752-k may be connected to the first output node. Again, all of the first and second pluralities of pulldown transistors 751-j, 752-k may be of a same transistor type (e.g., NMOS).

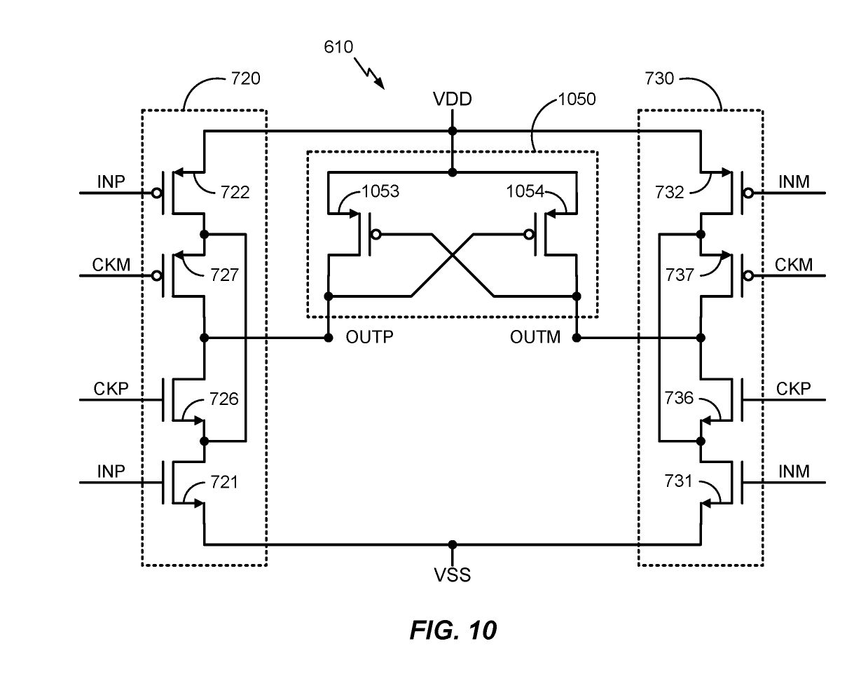

FIG. 10 illustrates a circuit diagram of another example latch device 610. The latch device 610 of FIG. 10 may represent one, some or all of the latch devices 610-n of the divider 600. The latch device 610 may include a tracking cell and a locking cell. The tracking cell may include first and second track inverters 720, 730 and the locking cell may include a differential latch 1050. The first and second track inverters 720, 730 of FIG. 10 may be similar to the first and second track inverters 720, 730 of FIG. 7. Therefore, the detailed description of the track inverters 720, 730 will be omitted.

The differential latch 1050 is also significantly different from the conventional differential latch 450 (compare FIGS. 4 and 10). The differential latch 1050 may include first and second pullup transistors 1053, 1054 cross-connected to each other. The first and second pullup transistors 1053, 1054 may be PMOS transistors whose sources may be connected to the high supply voltage. The drains of the first and second pullup transistors 1053, 1054 may respectively be connected to the first and second output node. The drain of the first pullup transistor 1053 and the first output node may be connected to the gate of the second pullup transistor 1054. Conversely, the drain of the second pullup transistor 1054 and the second output node may be connected to the gate of the first pullup transistor 1053.

The differential latch 1050 may include only PMOS transistors. More generally, it can be said that the differential latch 1050 may include a plurality of latch transistors that are all of a same transistor type. Also note that the differential latch 1050 is not directly connected to the low supply voltage. The differential latch 1050 may be electrically coupled to the low supply voltage only through the first and/or the second track inverters 720, 730.

The differential latch 1050 may be configured to lock the first and second output signals OUTP, OUTM at the first and second output nodes when the first and second track inverters 720, 730 are disabled, i.e., during the locking mode. That is, the differential latch 1050 may be configured to maintain the first and second output signals OUTP, OUTM during the locking mode when the first and second clock signals CKP, CKM are respectively low and high. Significantly, the differential latch 1050 may maintain the differential gain requirement of the first and second output signals OUTP, OUTM. That is, when the first output signal OUTP goes high, the second output signal OUTM is pulled low by the first and second pullup transistors 1053, 1054 and vice versa. In an aspect, the differential latch 1050 may be referred to as a pullup half latch.

While not shown, the amount of short-circuit current can be reduced significantly with the differential latch 1050. Like the situation with the differential latch 750, the short-circuit current paths 2 and 3 can be eliminated with the differential latch 1050. That is, the differential latch 1050 may be configured such that no current flows directly through the differential latch 1050 between the high and low supply voltages when the first and second output signals OUTP, OUTM transition between logical voltages. As a result, current consumption, and hence power consumption, can be reduced.

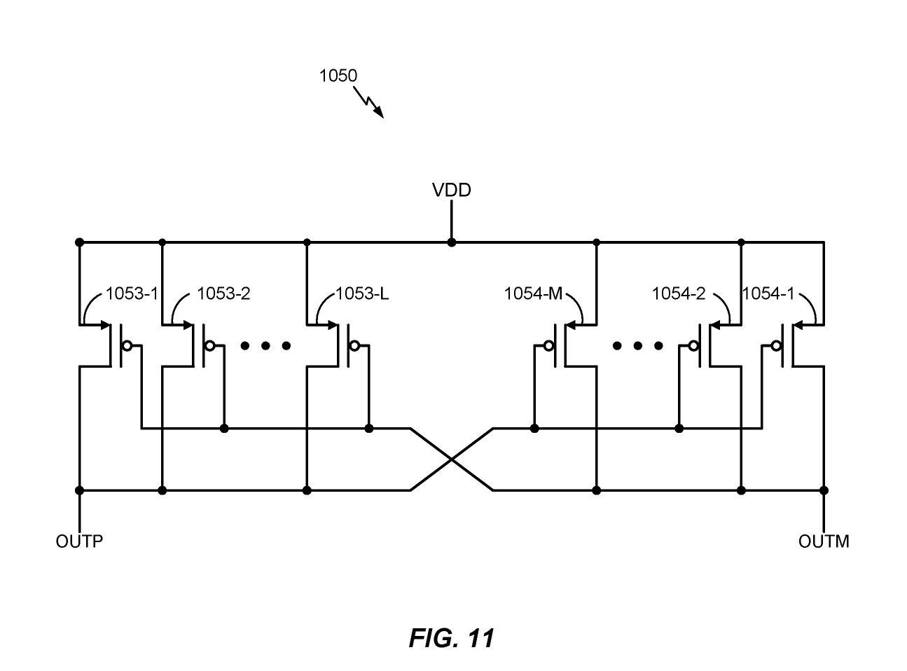

To maintain the differential gain requirement, the first and second pullup transistors 1053, 1054 may be sized to have sufficient driving capabilities (not shown). Alternatively or in addition thereto, multiple transistors may be connected in parallel with each other to provide sufficient driving capability as illustrated in FIG. 11. As seen, the first pullup transistor 1053 may be implemented to comprise a first plurality of pullup transistors 1053-l, where l=1 . . . L, and the second pullup transistor 1054 may be implemented to comprise a second plurality of pullup transistors 1054-m, where m=1 . . . M. The numbers L and M can be equal to each other or different from each other.

The first and second pluralities of pullup transistors 1053-l, 1054-m may be PMOS transistors whose sources may be connected to the high supply voltage. The drains of the first and second pluralities of pullup transistors 1053-l, 1054-m may respectively be connected to the first and second output nodes. The gates of the first pullup transistors 1053-l may be connected to the second output node, and the gates of the second pullup transistors 1054-m may be connected to the first output node. Again, all of the first and second pluralities of pullup transistors 1053-l, 1054-m may be of a same transistor type (e.g., PMOS).

Between the differential latch 750 (pulldown half latch) and the differential latch 1050 (pullup half latch), the differential latch 750 may be preferred. This is because between an NMOS transistor and a PMOS transistor of similar sizes, the NMOS transistor has higher driving capabilities. Therefore, for a given driving requirement, the differential latch 750 can be made smaller than the differential latch 1050. This can mean smaller capacitance at the output nodes, which in turn leads to improved slew rates.

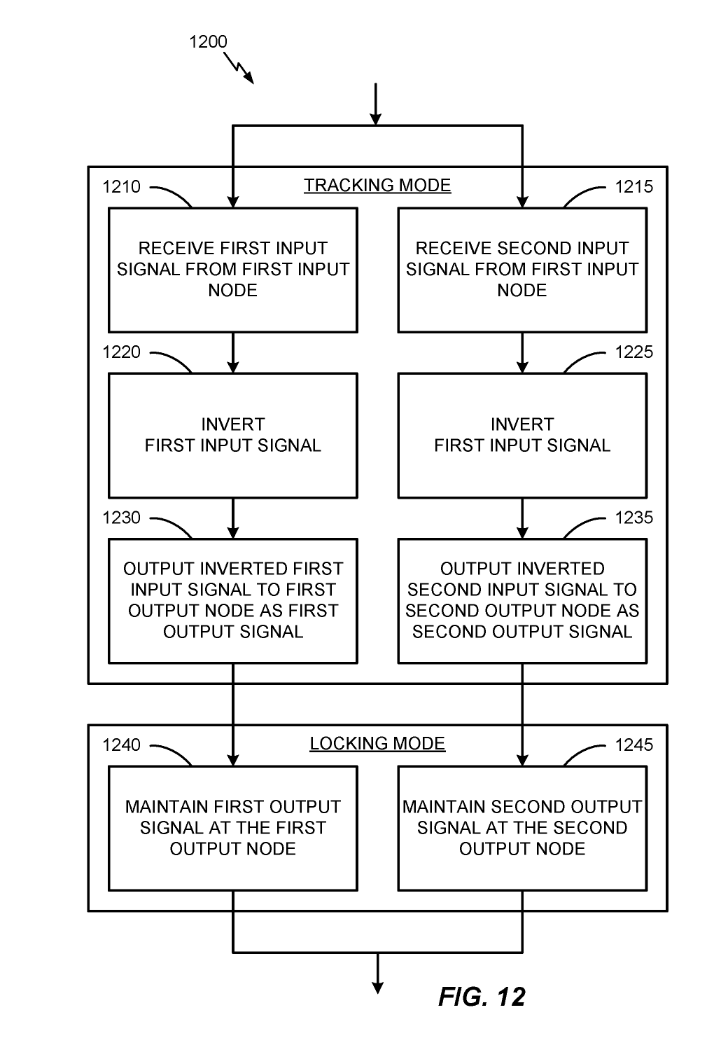

FIG. 12 is a flowchart of an example method 1200 of operating a latch device 610 of FIGS. 7 and 10. In FIG. 12, blocks 1210-1235 may be performed during the tracking mode, and blocks 1240 and 1245 may be performed during the locking mode. Blocks 1210, 1220 and 1230 may be performed by the first track inverter 720. In block 1210, the first track inverter 720 may receive the first input signal INP from the first input node. In block 1220, the first track inverter 720 may invert the received first input signal INP. In block 1230, the first track inverter 720 may output the inverted signal to the first output node as the first output signal OUTP.

Blocks 1215, 1225 and 1235 may be performed by the second track inverter 730. In block 1215, the second track inverter 730 may receive the second input signal INM from the second input node. In block 1225, the second track inverter 730 may invert the received second input signal INM. In block 1235, the second track inverter 730 may output the inverted signal to the second output node as the second output signal OUTM.

Blocks 1240 and 1245 may be performed by the differential latch 750, 1050. In block 1240, the differential latch 750, 1050 may maintain the first output signal OUTP at the logical value outputted by the first track inverter 720. In block 1250, the differential latch 750, 1050 may maintain the second output signal OUTM at the logical value outputted by the second track inverter 730.

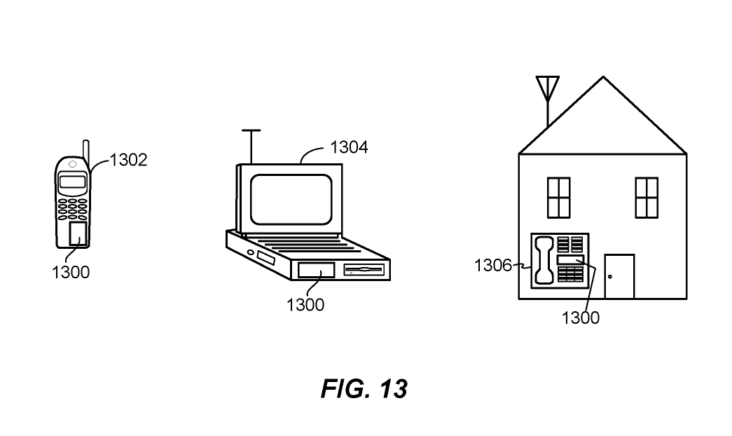

FIG. 13 illustrates various electronic devices that may be integrated with the aforementioned apparatuses illustrated in FIGS. 6-11. For example, a mobile phone device 1302, a laptop computer device 1304, a terminal device 1306 as well as wearable devices, portable systems, that require small form factor, extreme low profile, may include an apparatus 1300 that incorporates the devices/systems as described herein. The apparatus 1300 may be, for example, any of the integrated circuits, dies, integrated devices, integrated device packages, integrated circuit devices, device packages, integrated circuit (IC) packages, package-on-package devices, system-in-package devices described herein. The devices 1302, 1304, 1306 illustrated in FIG. 13 are merely exemplary. Other electronic devices may also feature the device/package 1300 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), or any other device that stores or retrieves data or computer instructions, or any combination thereof.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithms described in connection with the examples disclosed herein may be implemented as electronic hardware, computer software, or combinations of both. To clearly illustrate this interchangeability of hardware and software, various illustrative components, blocks, modules, circuits, and methods have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The methods, sequences and/or algorithms described in connection with the examples disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled with the processor such that the processor can read information from, and write information to, the storage medium. In the alternative, the storage medium may be integral to the processor.

Accordingly, an aspect can include a computer-readable media embodying any of the devices described above. Accordingly, the scope of the disclosed subject matter is not limited to illustrated examples and any means for performing the functionality described herein are included.

While the foregoing disclosure shows illustrative examples, it should be noted that various changes and modifications could be made herein without departing from the scope of the disclosed subject matter as defined by the appended claims. The functions, processes and/or actions of the method claims in accordance with the examples described herein need not be performed in any particular order. Furthermore, although elements of the disclosed subject matter may be described or claimed in the singular, the plural is contemplated unless limitation to the singular is explicitly stated.

What is claimed is:

1. A latch device, comprising:
first and second input nodes, first and second output nodes, and first and second clock nodes;
a first track inverter configured to:
receive a first input signal from the first input node, and
output a first output signal to the first output node during a tracking mode, the first output signal being logically complementary to the first input signal;
a second track inverter configured to:
receive a second input signal from the second input node, the second input signal being logically complementary to the first input signal, and
output a second output signal to the second output node during the tracking mode, the second output signal being logically complementary to the second input signal;
a differential latch configured to maintain the first output signal at the first output node and maintain the second output signal at the second output node during a locking mode,
wherein the tracking mode and the locking mode are defined based on states of the first and second clock signals respectively received at the first and second clock nodes such that the first and second track inverters are enabled during the tracking mode and are disabled during the locking mode, and
wherein the differential latch comprises a plurality of latch transistors that are all of a same transistor type.

2. The latch device of claim 1,
wherein the plurality of latch transistors of the differential latch comprise first and second pulldown transistors,
wherein the first and the second pulldown transistors are both NMOS transistors,
wherein both sources of the first and the second pulldown transistors are connected to a low supply voltage,
wherein a drain of the first pulldown transistor is connected
to the first output node and
to a gate of the second pulldown transistor, and
wherein a drain of the second pulldown transistor is connected
to the second output node and
to a gate of the first pulldown transistor.

3. The latch device of claim 2,
wherein the first pulldown transistor comprises a first plurality of pulldown transistors connected in parallel with each other, or
wherein the second pulldown transistor comprises a second plurality of pulldown transistors connected in parallel with each other, or
both.

4. The latch device of claim 2, wherein the differential latch is not directly connected to a high supply voltage.

5. The latch device of claim 4, wherein the differential latch is connected to the high supply voltage only through one or both of the first and second track inverters.

6. The latch device of claim 1,
wherein the plurality of latch transistors of the differential latch comprises first and second pullup transistors,
wherein the first and the second pullup transistors are both PMOS transistors,
wherein both sources of the first and the second pullup transistors are connected to a high supply voltage,
wherein a drain of the first pullup transistor is connected
to the first output node and
to a gate of the second pullup transistor, and
wherein a drain of the second pullup transistor is connected
to the second output node and
to a gate of the first pullup transistor.

7. The latch device of claim 6,
wherein the first pullup transistor comprises a first plurality of pullup transistors connected in parallel with each other, or
wherein the second pullup transistor comprises a second plurality of pullup transistors connected in parallel with each other, or
both.

8. The latch device of claim 6, wherein the differential latch is not directly connected to a low supply voltage.

9. The latch device of claim 8, wherein the differential latch is connected to the low supply voltage only through one or both of the first and second track inverters.

10. The latch device of claim 1, wherein the differential latch is configured such that no current flows directly through the differential latch between high and low supply voltages when the first and second output signals transition between logical voltages.

11. A ring oscillator, comprising:
a plurality of latch devices connected in a ring configuration, each latch device comprising first and second input nodes, first and second output nodes, and first and second clock nodes,
wherein at least one latch device of the plurality of latch devices comprises:
a first track inverter configured to:
receive a first input signal from the first input node, and
output a first output signal to the first output node during a tracking mode, the first output signal being logically complementary to the first input signal;
a second track inverter configured to:
receive a second input signal from the second input node, the second input signal being logically complementary to the first input signal, and
output a second output signal to the second output node during the tracking mode, the second output signal being logically complementary to the second input signal;
a differential latch configured to maintain the first output signal at the first output node and maintain the second output signal at the second output node during a locking mode,
wherein the tracking mode and the locking mode are defined based on states of the first and second clock signals respectively received at the first and second clock nodes such that the first and second track inverters are enabled during the tracking mode and are disabled during the locking mode, and
wherein the differential latch comprises a plurality of latch transistors that are all of a same transistor type.

12. The ring oscillator of claim 11,
wherein the plurality of latch transistors of the differential latch comprise first and second pulldown transistors,
wherein the first and the second pulldown transistors are both NMOS transistors,
wherein both sources of the first and the second pulldown transistors are connected to a low supply voltage,
wherein a drain of the first pulldown transistor is connected
to the first output node and
to a gate of the second pulldown transistor, and
wherein a drain of the second pulldown transistor is connected
to the second output node and
to a gate of the first pulldown transistor.

13. The ring oscillator of claim 12,
wherein the first pulldown transistor comprises a first plurality of pulldown transistors connected in parallel with each other, or
wherein the second pulldown transistor comprises a second plurality of pulldown transistors connected in parallel with each other, or
both.

14. The ring oscillator of claim 12, wherein the differential latch is not directly connected to a high supply voltage.

15. The ring oscillator of claim 14, wherein the differential latch is connected to the high supply voltage only through one or both of the first and second track inverters.

16. The ring oscillator of claim 11,
wherein the plurality of latch transistors of the differential latch comprises first and second pullup transistors,
wherein the first and the second pullup transistors are both PMOS transistors,
wherein both sources of the first and the second pullup transistors are connected to a high supply voltage,
wherein a drain of the first pullup transistor is connected
to the first output node and
to a gate of the second pullup transistor, and
wherein a drain of the second pullup transistor is connected
to the second output node and
to a gate of the first pullup transistor.

17. The ring oscillator of claim 16,
wherein the first pullup transistor comprises a first plurality of pullup transistors connected in parallel with each other, or
wherein the second pullup transistor comprises a second plurality of pullup transistors connected in parallel with each other, or
both.

18. The ring oscillator of claim 16, wherein the differential latch is not directly connected to a low supply voltage.

19. The ring oscillator of claim 18, wherein the differential latch is connected to the low supply voltage only through one or both of the first and second track inverters.

20. The ring oscillator of claim 11, wherein the differential latch is configured such that no current flows directly through the differential latch between high and low supply voltages when the first and second output signals transition between logical voltages.

21. The ring oscillator of claim 11,
wherein between any two immediately adjacent latch devices,
the first and second output nodes of a previous latch device are respectively connected to the first and second input nodes of a subsequent latch device,
the first clock node of the previous latch device and the second clock node of the subsequent latch device receive a first common clock signal,
the second clock node of the previous latch device and the first clock node of the subsequent latch device receive a second common clock signal, and
wherein the first and second output nodes of a last latch device are respectively connected to the second and first input nodes of a first latch device.

22. The ring oscillator of claim 11, wherein a number of the plurality of latch devices is even.

23. A method of operating a latch device comprising first and second input nodes, first and second output nodes, first and second clock nodes, a first track inverter, a second track inverter, and a latch device, the method comprising,
receiving, at the first track inverter, a first input signal from the first input node;
outputting, by the first track inverter, a first output signal to the first output node during a tracking mode, the first output signal being logically complementary to the first input signal;
receiving, at the second track inverter, a second input signal from the second input node, the second input signal being logically complementary to the first input signal;
outputting, by the second track inverter, a second output signal to the second output node during the tracking mode, the second output signal being logically complementary to the second input signal;
maintaining, by the differential latch, the first output signal at the first output node and the second output signal at the second output node during a locking mode,
wherein the tracking mode and the locking mode are defined based on states of the first and second clock signals respectively received at the first and second clock nodes such that the first and second track inverters are enabled during the tracking mode and are disabled during the locking mode, and
wherein the differential latch comprises a plurality of latch transistors that are all of a same transistor type.

24. A latch device, comprising:
first and second input nodes, first and second output nodes, and first and second clock nodes; and
means for tracking and means for locking,
wherein the means for tracking comprises:
means for tracking a first input signal for
receiving the first input signal from the first input node, and
outputting a first output signal to the first output node during a tracking mode, the first output signal being logically complementary to the first input signal; and
means for tracking a second input signal for
receiving the second input signal from the second input node, the second input signal being logically complementary to the first input signal, and
outputting a second output signal to the second output node during the tracking mode, the second output signal being logically complementary to the second input signal,
wherein the means for locking maintains the first output signal at the first output node and maintains the second output signal at the second output node during a locking mode,
wherein the tracking mode and the locking mode are defined based on states of the first and second clock signals respectively received at the first and second clock nodes such that the means for tracking is enabled during the tracking mode and is disabled during the locking mode, and
wherein the means for locking comprise a plurality of locking transistors that are all of a same transistor type.

25. The latch device of claim 1, wherein the latch device is incorporated into a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in an automotive vehicle.

26. The ring oscillator of claim 11, wherein the ring oscillator is incorporated into a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in an automotive vehicle.
